(19) United States
(12) Patent Application Publication
(10) Pub. No.: US 2025/0338567 A1
(43) Pub. Date: Oct. 30, 2025

(54) LOWERING PMOSFET THRESHOLD VOLTAGE THROUGH TERNARY-ELEMENT NITRIDE

(71) Applicant: Taiwan Semiconductor Manufacturing Co., Ltd., Hsinchu (TW)

(72) Inventors: Tsung-Han Shen, Taoyuan City (TW); Sheng-Yung Chang, Hsinchu (TW); Ying Chih Wu, Taoyuan City (TW); Chin-You Hsu, Hsinchu (TW); Chung-Yi Su, Taipei City (TW); Kuan-Ting Liu, Hsinchu (TW); Weng Chang, Hsinchu (TW); Chi On Chui, Hsinchu (TW)

(21) Appl. No.: 19/261,092

(22) Filed: Jul. 7, 2025

Related U.S. Application Data
(63) Continuation of application No. 18/747,660, filed on Jun. 19, 2024.
(60) Provisional application No. 63/575,053, filed on Apr. 5, 2024.

(51) Int. Cl. H10D 30/69; H10D 30/62; H10D 62/13; H10D 62/85; H10D 64/01

(52) U.S. Cl. CPC H10D 30/751; H10D 30/62; H10D 62/151; H10D 62/8503; H10D 64/017

(57) ABSTRACT

A method includes forming a p-type transistor. The method includes forming a gate dielectric on a semiconductor region, and depositing a p-type work-function layer on the gate dielectric. The p-type work-function layer includes a metal nitride, which includes a first metal and a second metal. An n-type work-function layer is deposited over the p-type work-function layer. A p-type source/drain region is formed aside of the semiconductor region.

### PRIORITY CLAIM AND CROSS-REFERENCE

This application is a continuation of U.S. patent application Ser. No. 18/747,660, filed on Jun. 19, 2024, which application claims the benefit of the following provisionally filed U.S. Patent application: Application No. 63/575,053, filed on Apr. 5, 2024, and entitled “LOWERING PMOSFET THRESHOLD VOLTAGE BY TERNARY-ELEMENT NITRIDE FOR ENHANCED ALUMINUM DIFFUSION BLOCKING ABILITY;” which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through FIGS. 17A, 17B, and 17C illustrate the intermediate stages in the formation of a p-type Gate-All-Around (GAA) transistor and an n-type (GAA) transistor in accordance with some embodiments.

FIG. 18 illustrates example WCN/TiN ternary layers in accordance with some embodiments.

FIGS. 19-21 illustrate the sequences of depositing WCN/TiN ternary layers in accordance with some embodiments.

FIGS. 22-24 illustrate some example multilayer stacks including WCN and TiN layers in accordance with some embodiments.

FIGS. 25 and 26 illustrate some samples and performance results in accordance with some embodiments.

FIGS. 27A and 27B illustrate some gate stacks and the flat-band voltages of the gate stacks in accordance with some embodiments.

FIG. 28 illustrates an element distribution profile of a gate stack in accordance with some embodiments.

FIG. 29 illustrates the distribution of some elements in a WCN/TiN sample in accordance with some embodiments.

FIG. 30 illustrates a process flow for forming transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A method of reducing aluminum diffusion in the formation of transistors is provided. In accordance with some embodiments of the present disclosure, a ternary p-type work-function layer is formed, which includes a first metal nitride mixed with a second metal nitride. An n-type work-function layer comprising aluminum is formed over the ternary p-type work-function layer. The first metal nitride in the ternary p-type work-function layer provides the p-type work function. The second metal nitride in the ternary p-type work-function layer is configured to reduce the downward diffusion of the aluminum in the overlying n-type work-function layer. It is appreciated that although Gate-All-Around (GAA) transistors are used as an example, the concept of the present disclosure may be applied to other types of transistors such as planar transistors, Fin Field-Effect Transistors (FinFETs), Complementary Field-Effect Transistors (CFETs), and the like.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

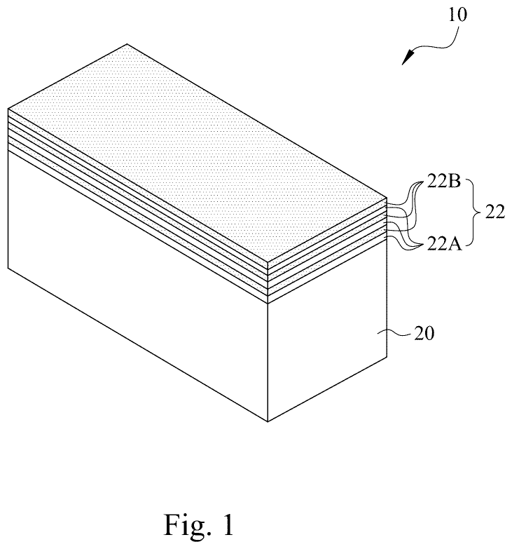

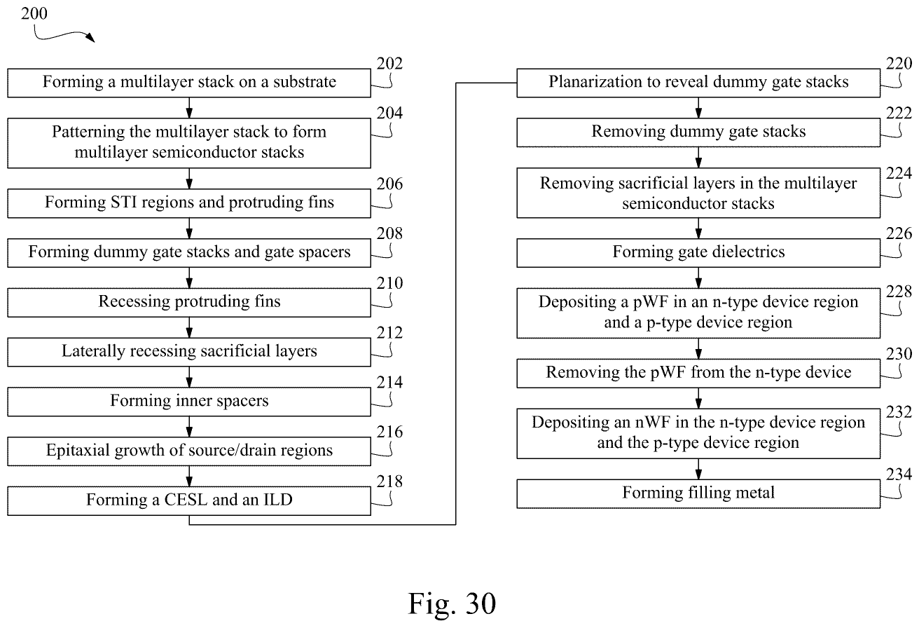

FIG. 1 through FIGS. 17A, 17B, and 17C illustrate the intermediate stages in the formation of an n-type GAA transistor and a p-type GAA transistor in accordance with some embodiments. The corresponding processes are also reflected schematically in the process flow as shown in FIG. 30.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 shown in FIG. 30. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22B may be formed to a second thickness in the range between about 10 Å and about 500 Å, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there are some pad oxide layer(s) and hard mask layer(s) (not shown) formed over multilayer stack 22. These layers are patterned, and are used for the subsequent patterning of multilayer stack 22.

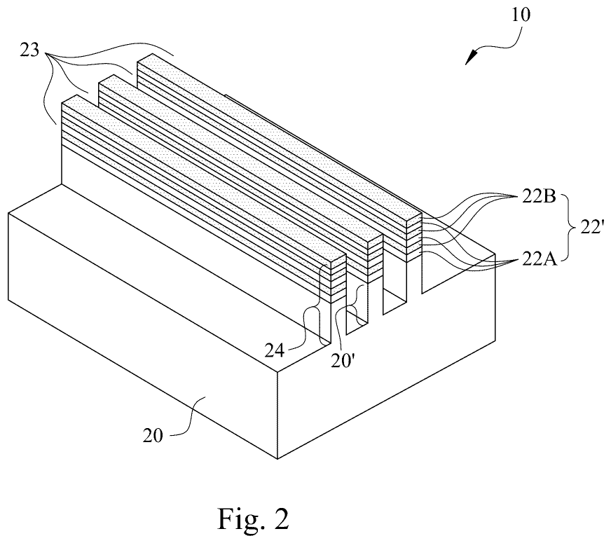

Referring to FIG. 2, multilayer stack 22 and a portion of the underlying substrate 20 are patterned in an etching process(es), so that trenches 23 are formed. The respective process is illustrated as process 204 in the process flow 200 shown in FIG. 30. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

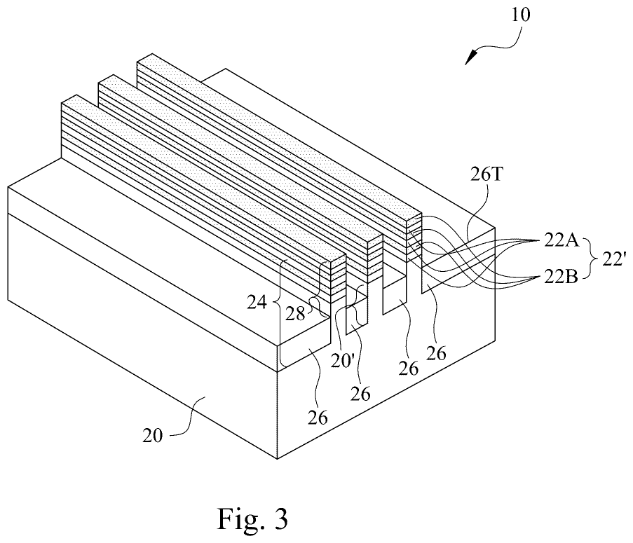

FIG. 3 illustrates the formation of isolation regions 26, which are also referred to as Shallow Trench Isolation (STI) regions throughout the description. The respective process is illustrated as process 206 in the process flow 200 shown in FIG. 30. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

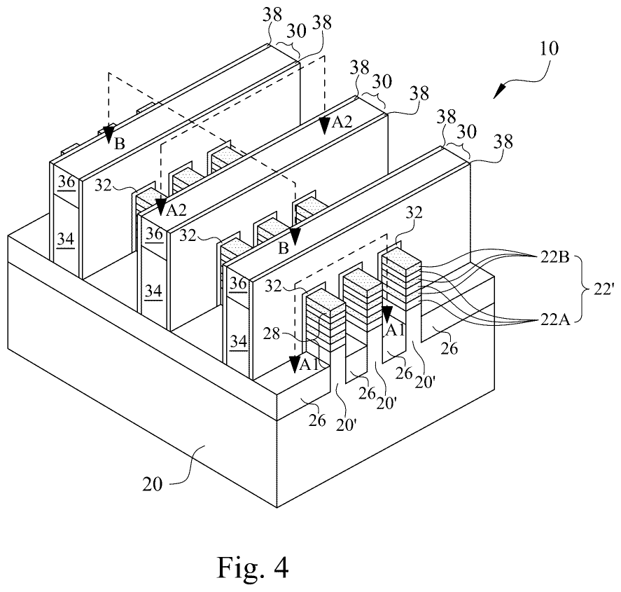

Referring to FIG. 4, dummy gate stacks 30 and gate spacers 38 are formed on the top surfaces and the sidewalls of (protruding) fins 28. The respective process is illustrated as process 208 in the process flow 200 shown in FIG. 30. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

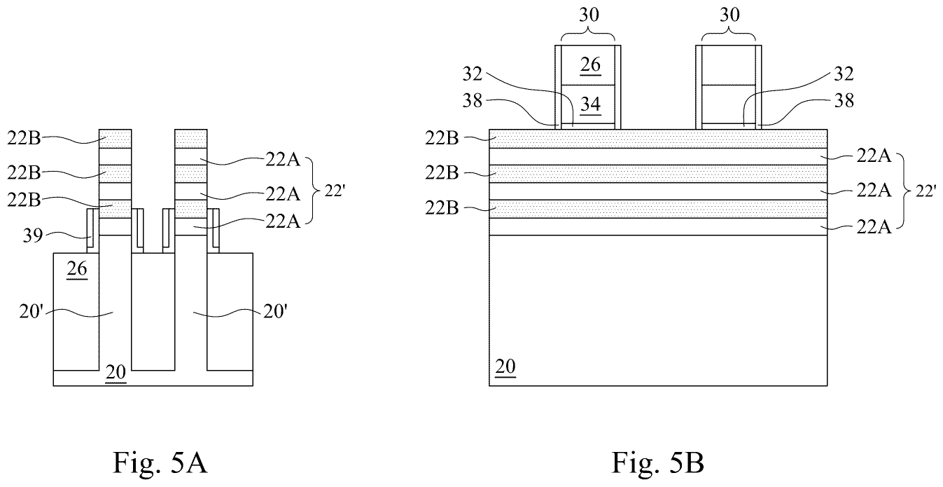

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by gate stacks 30 and gate spacers 38, and is perpendicular to the gate-length direction. Fin spacers 38, which are on the sidewalls of protruding fins 28, are also illustrated. FIG. 5B illustrates the reference cross-section B-B in FIG. 4, which reference cross-section is parallel to the lengthwise directions of protruding fins 28. Fin spacers 39 are also illustrated.

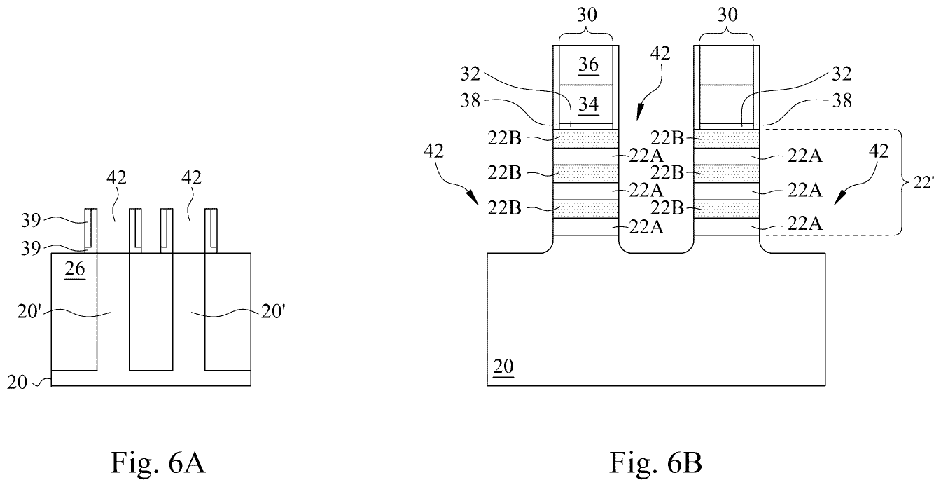

Referring to FIGS. 6A and 6B, the portions of protruding fins 28 that are not directly underlying dummy gate stacks 30 and gate spacers 38 are recessed through an etching process to form recesses 42. The respective process is illustrated as process 210 in the process flow 200 shown in FIG. 30. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

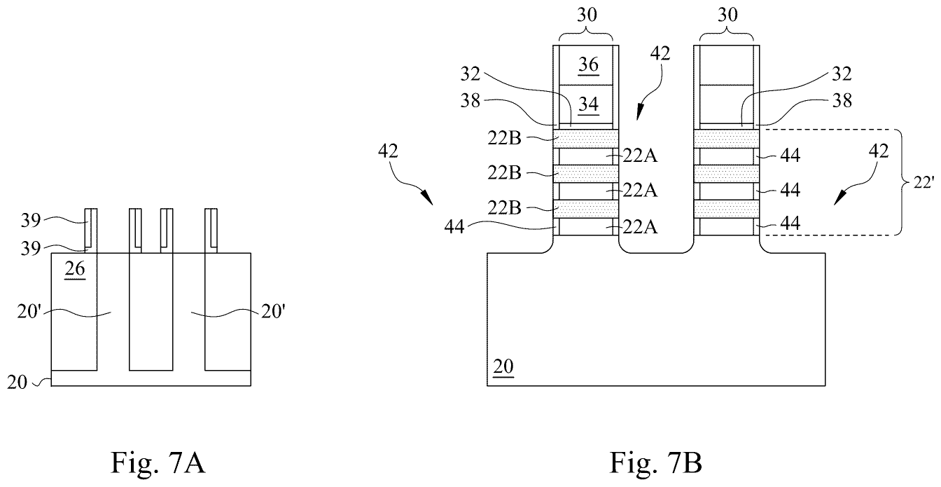

Referring to FIGS. 7A and 7B, inner spacers 44 are formed. The formation process may include laterally recessing sacrificial semiconductor layers 22A to form lateral recesses (occupied by inner spacers 44), which are recessed from the edges of the respective overlying and underlying nanostructures 22B. The respective process is illustrated as process 212 in the process flow 200 shown in FIG. 30. The lateral recessing of sacrificial semiconductor layers 22A may be achieved through a wet etching process or an isotropic dry etching process or a combination of a dry etching process and a wet etching process.

Inner spacers 44 are then formed in the lateral recesses. The respective process is illustrated as process 214 in the process flow 200 shown in FIG. 30. The formation process incudes depositing a dielectric spacer layer extending into the lateral recesses, and performing an etching process to remove the portions of dielectric spacer layer outside of lateral recesses, thus leaving inner spacers 44 in the recesses. Inner spacers 44 may be formed of or comprise SiOCN, SiON, SiOC, SiCN, or the like.

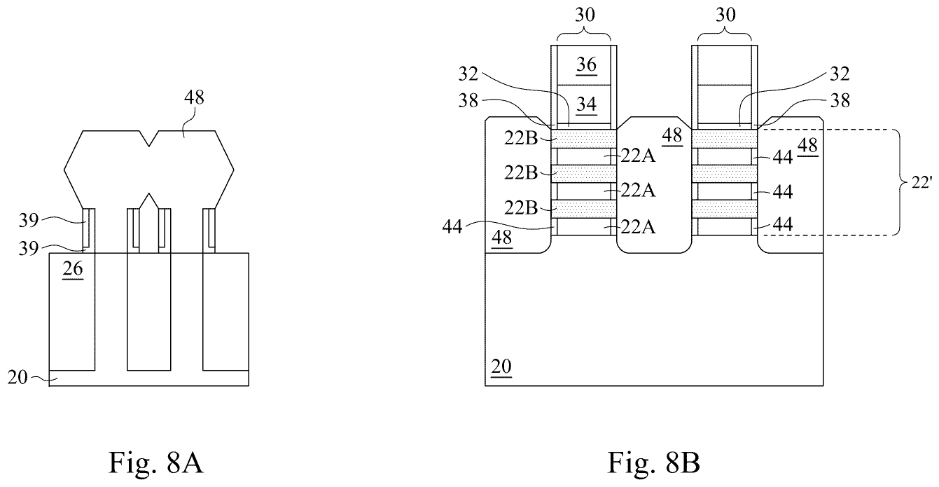

Referring to FIGS. 8A and 8B, epitaxial source/drain regions 48 are formed in recesses 42 through selective epitaxy growth. The respective process is illustrated as process 216 in the process flow 200 shown in FIG. 30. Depending on whether the resulting FinFET is a p-type FinFET or an n-type FinFET, a p-type or an n-type impurity may be in-situ doped with the proceeding of the epitaxy. For example, when the resulting FinFET is a p-type FinFET, epitaxial source/drain regions 48 may comprise silicon germanium boron (SiGeB), silicon boron (SiB), or the like. Conversely, when the resulting FinFET is an n-type FinFET, epitaxial source/drain regions 48 may comprise silicon phosphorous (SiP), silicon carbon phosphorous (SiCP), or the like. After recesses 42 are filled with epitaxy regions 48, the further epitaxial growth of epitaxy regions 48 causes epitaxy regions 48 to expand horizontally, and facets may be formed.

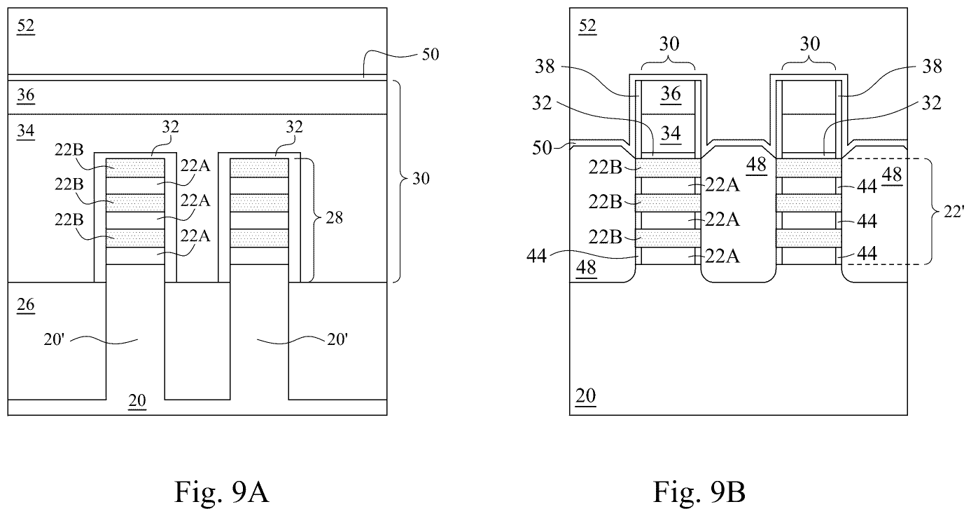

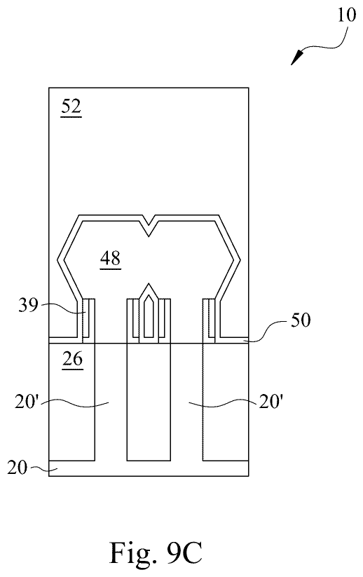

FIGS. 9A, 9B, and 9C illustrate the cross-sectional views of the structure after the formation of Contact Etch Stop Layer (CESL) 50 and Inter-Layer Dielectric (ILD) 52. FIGS. 9A, 9B, and 9C are obtained from the same cross-section same as the cross-sections A2-A2, B-B, and A1-A1, respectively, in FIG. 4. The respective process is illustrated as process 218 in the process flow 200 shown in FIG. 30. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may comprise silicon oxide, Phospho-Silicate Glass (PSG), Boro-Silicate Glass (BSG), Boron-Doped Phospho-Silicate Glass (BPSG), Undoped Silicate Glass (USG), or the like.

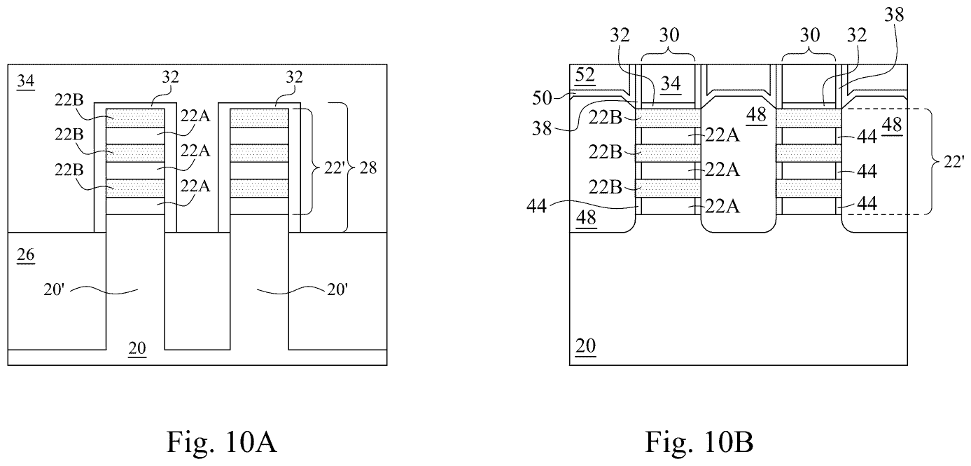

In subsequent processes, replacement gate stacks are formed to replace dummy gate stacks 30. Referring to FIGS. 10A and 10B, a planarization process such as a CMP process or a mechanical grinding process is performed to level the top surface of ILD 52. The respective process is illustrated as process 220 in the process flow 200 shown in FIG. 30. In accordance with some embodiments, the planarization process may remove hard masks 36 to reveal dummy gate electrodes 34, as shown in FIG. 10B. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level with each other within process variations.

Next, dummy gate electrodes 34 (and hard masks 36, if remaining) are removed in one or more etching processes, so that recesses 58 are formed, as shown in FIGS. 11A and 11B. The respective process is illustrated as process 222 in the process flow 200 shown in FIG. 30. The portions of the dummy gate dielectrics 32 in recesses 58 are also removed.

Sacrificial layers 22A are then removed to extend recesses 58 between nanostructures 22B, and the resulting structure is also shown in FIGS. 11A and 11B. The respective process is illustrated as process 224 in the process flow 200 shown in FIG. 30. Sacrificial layers 22A may be removed by performing an isotropic etching process such as a wet etching process using etchants which are selective to the materials of sacrificial layers 22A. Nanostructures 22B, substrate 20, and STI regions 26 remain relatively un-etched as compared to sacrificial layers 22A. In accordance with some embodiments in which sacrificial layers 22A include, for example, SiGe, and nanostructures 22B include, for example, Si or SiC, etching chemicals such as tetra methyl ammonium hydroxide (TMAH), ammonium hydroxide (NH4OH), or the like may be used to remove sacrificial layers 22A.

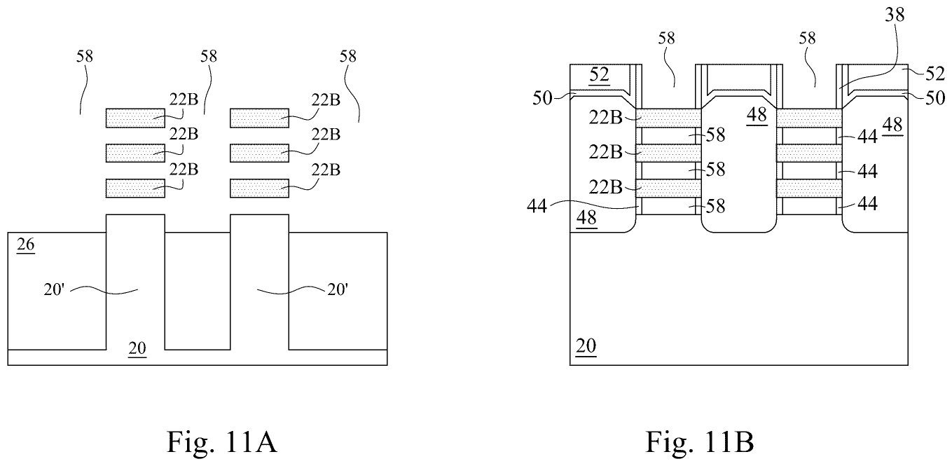

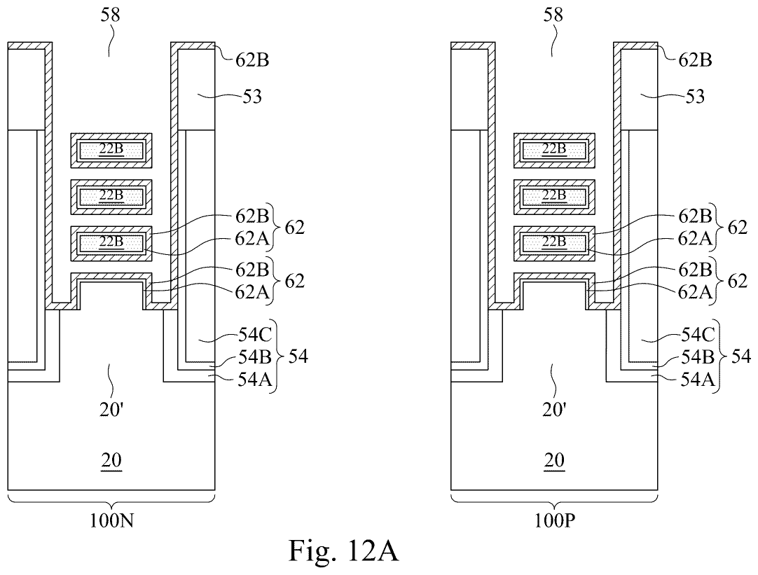

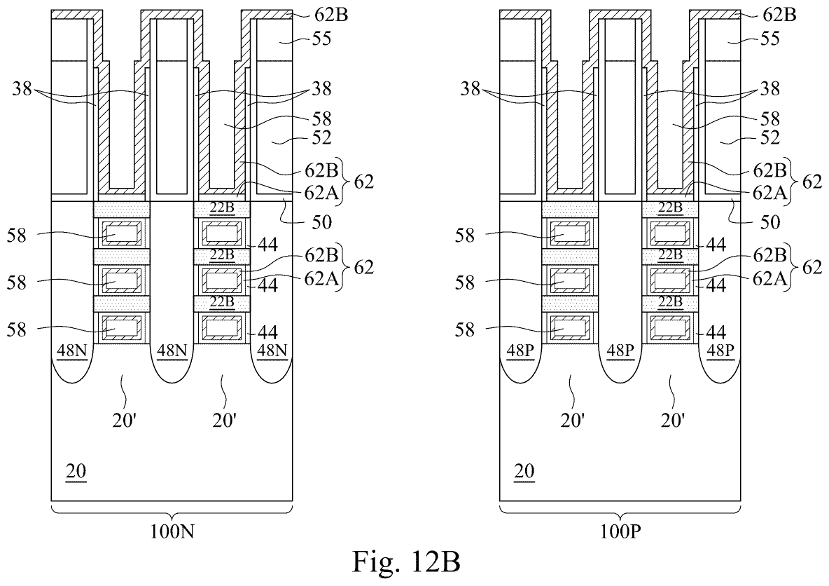

The preceding processes may be shared by the formation of multiple GAA transistors. In subsequent discussion, as shown in FIGS. 12A and 12B, device regions 100N and 100P are illustrated, in which an n-type transistor and a p-type transistor, respectively, are to be formed. Each of the n-type transistor and the p-type transistor may be formed sharing the processes shown in preceding figures. The subsequent figures with the figure numbers including letters “A” and “B” are obtained from the cross-sections A2-A2 and B-B, respectively, in FIG. 4.

FIG. 12A illustrates the device regions 100N and 100P, wherein the illustrated cross-sections are the same cross-sections as the cross-section A2-A2 in FIG. 4. In accordance with some embodiments, differing from FIG. 4, dielectric fins 54 (sometimes referred to as hybrid fins) (FIG. 12A) are formed between neighboring multilayer stacks. Dielectric fins 54 separate neighboring nanostructures 22B and neighboring transistors in accordance with other embodiments. In other embodiments as shown in FIG. 4, neighboring multilayer stacks do not have dielectric fins in between.

In accordance with some embodiments, as shown in FIG. 12A, dielectric fins 54 include a plurality of dielectric layers such as dielectric layers 54A, 54B, and 54C, with neighboring dielectric layers being formed of different materials. Hard mask 53 may be formed over dielectric fins 54, and may be formed of silicon nitride, silicon oxynitride, or the like.

As also shown in FIGS. 12A and 12B, gate dielectrics 62 are formed. The respective process is illustrated as process 226 in the process flow 200 shown in FIG. 30. In accordance with some embodiments, each of gate dielectrics 62 includes interfacial layer 62A and high-k dielectric layer 62B on the interfacial layer 62A. The interfacial layer 62A may be formed of or comprise silicon oxide, which may be deposited through a conformal deposition process such as ALD or CVD. In accordance with alternative embodiments, interfacial layer 62A is formed through thermal oxidation. In accordance with some embodiments, the high-k dielectric layers 62B comprise one or more dielectric layers. For example, the high-k dielectric layer(s) 62B may include a metal oxide or a silicate of hafnium, aluminum, zirconium, lanthanum, manganese, barium, titanium, lead, combinations thereof, and/or multi-layers thereof.

Referring to FIG. 12B, the illustrated cross-sections are the cross-section B-B in FIG. 4. Accordingly, n-type source/drain regions 48N and p-type source/drain regions 48P are illustrated in device regions 100N and 100P, respectively. Hard mask 55 may be formed on top of CESL 50 and ILD 52. The hard mask 55 may be formed of silicon nitride, silicon oxynitride, or the like. High-k dielectric layer 62 thus may extend over hard mask 53.

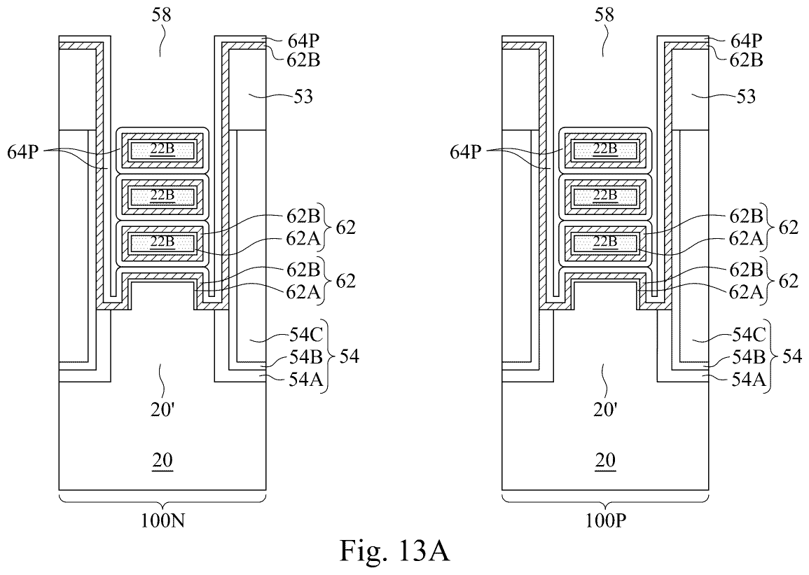

FIGS. 13A and 13B illustrate the deposition of p-type work-function layer (pWF) 64P in accordance with some embodiments. The respective process is illustrated as process 228 in the process flow 200 shown in FIG. 30. In accordance with some embodiments, p-type work-function layer 64P include a first metal nitride and a second metal nitride, which are deposited separately, and possibly alternatingly. The first metal nitride provides the p-type work function (higher than about 4.6 eV, for example). The first metal nitride may include titanium nitride, tantalum nitride, or the like in accordance with some embodiments.

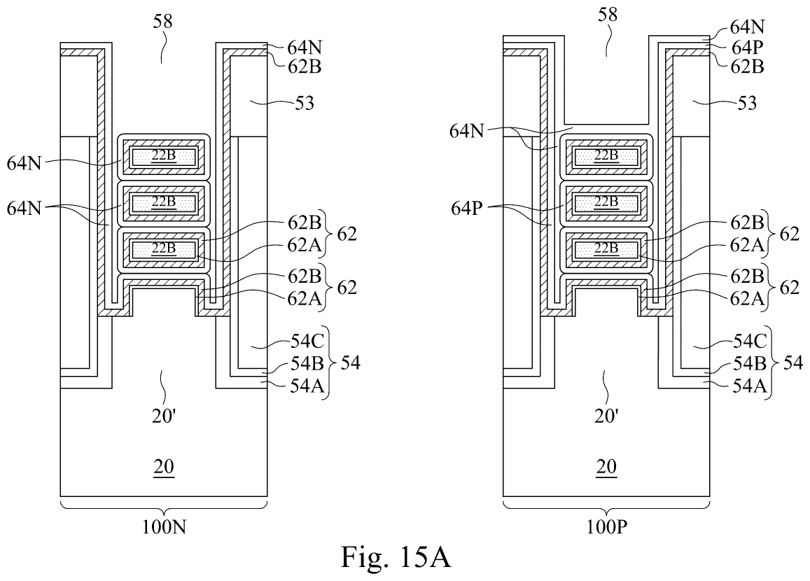

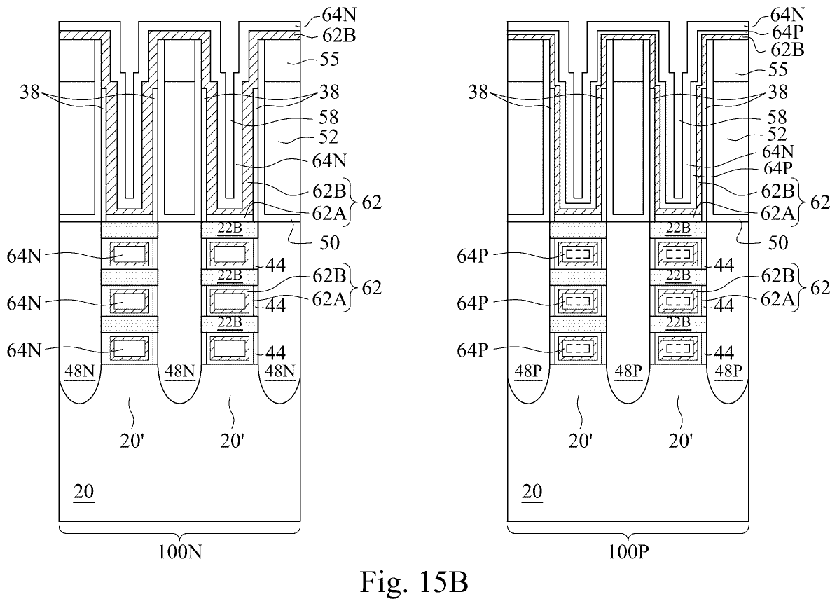

The second metal nitride is capable of reducing the diffusion of the aluminum in the subsequently deposited n-type work-function layer 64N (FIGS. 15A and 15B) from diffusing into the p-type work-function layer 64P and lower layers such as the high-k dielectric layer 62B. In accordance with some embodiments, the second metal nitride comprises tungsten carbonate nitride (WCN), molybdenum nitride (MoN), tantalum nitride (TaN), vanadium nitride (VN), or the like, or combinations thereof.

In subsequent discussion, the first metal nitride adopts TiN as an example, and the second metal nitride adopts WCN as an example. The concept may also be applied to other materials as discussed above. In accordance with some embodiments, a TiN layer is deposited through ALD, and may be deposited through one or a plurality of (2, 3, 4, 5, or more) ALD cycles. A WCN layer may also be deposited through ALD and in contact with the TiN layer, and may be deposited through one or a plurality of (2, 3, 4, 5, or more) ALD cycles. The TiN layer and the WCN layer, when being thin and contacting each other, will inter-diffuse in subsequent thermal processes, and intermix with each other to form a ternary layer, which is also referred to as a WCN/TiN ternary layer. The formation of a TiN layer and a WCN layer is referred to as a ternary cycle. In the formation of the p-type work-function layer, the ternary cycle may or may not be repeated. The resulting p-type work-function layer 64P thus may include a single ternary layer or a plurality of ternary layers.

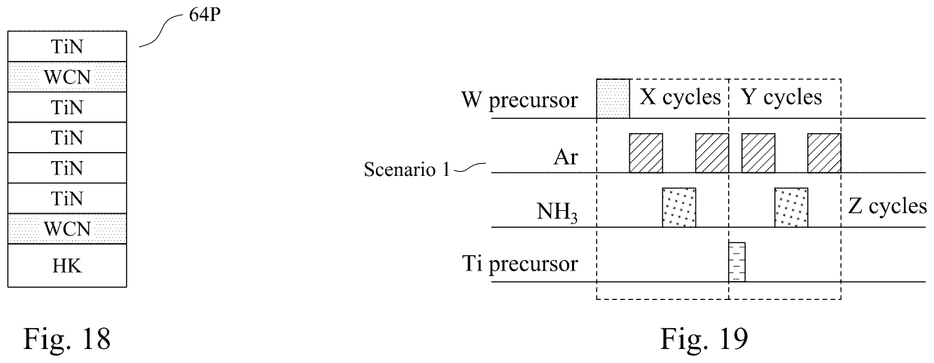

FIG. 18 illustrates an example p-type work-function layer 64P in accordance with some example embodiments. The p-type work-function layer 64P includes a first WCN layer on a high-k (HK) dielectric layer. The first WCN layer is formed through a single ALD cycle. A first TiN layer is then formed through 4 ALD cycles. A second WCN layer is then formed through a single ALD cycle, followed by the formation of a second TiN layer including one or more ALD cycles.

FIGS. 19, 20, and 21 illustrate some example ALD cycles for depositing the p-type work-function layer 64P in accordance with some embodiments. FIG. 19 illustrates a first scenario (scenario 1) representing a sequence of conducting (pulsing) and purging the corresponding process gases and precursors. The time sequence is from left to right, and the corresponding process gases are illustrated. When a rectangular block is shown for a process gas, the process gas is conducted at the corresponding time. At the times no rectangular block is shown for a process gas, the process gas is not conducted at the corresponding time.

FIG. 19 illustrates the deposition of WCN followed by the deposition of TiN in accordance with some embodiments. The WCN ALD cycle includes pulsing a tungsten-containing precursor (which may also include carbon), purging the tungsten-containing precursor using an inert gas (such as Ar), pulsing a nitrogen-containing gas such as ammonia (NH₃), and purging the nitrogen-containing gas using the inert gas. An atomic layer of WCN is thus formed. The WCN ALD cycle may be (or may not be) repeated X times (with X being 2 or more) to form several WCN atomic layers.

In accordance with some embodiments, the tungsten-containing precursor may comprise a halide-based tungsten-containing precursor or a metal-organo based tungsten-containing precursor. The halide-based tungsten-containing precursor may include WF₆, WCl₆, or the like. The metal-organo tungsten-containing precursor may include Tungsten hexacarbonyl (also known as tungsten carbonyl, W(CO)₆), Bis(ethylcyclopentadienyl)Tungsten, (Bis(tert-butylimino)bis(dimethylamino)tungsten(VI), or the like.

The TiN ALD cycle includes pulsing a titanium-containing precursor, purging the titanium-containing precursor using an inert gas (such as Ar, nitrogen, or the like), pulsing a nitrogen-containing gas such as ammonia (NH₃), and purging the nitrogen-containing gas. An atomic layer of TiN is thus formed. The titanium-containing precursor may include tetrakis(dimethylamino)titanium (TDMAT), TiCl₄, or the like. The TiN ALD cycle may be (or may not be) repeated Y times (with Y being 2 or more) to form several TiN atomic layers. The ternary cycle including the deposition of WCN and the deposition of TiN may be, or may not be, repeated Z times, with integer Z being 2 or more, which concludes the deposition of the p-type work-function layer 64P.

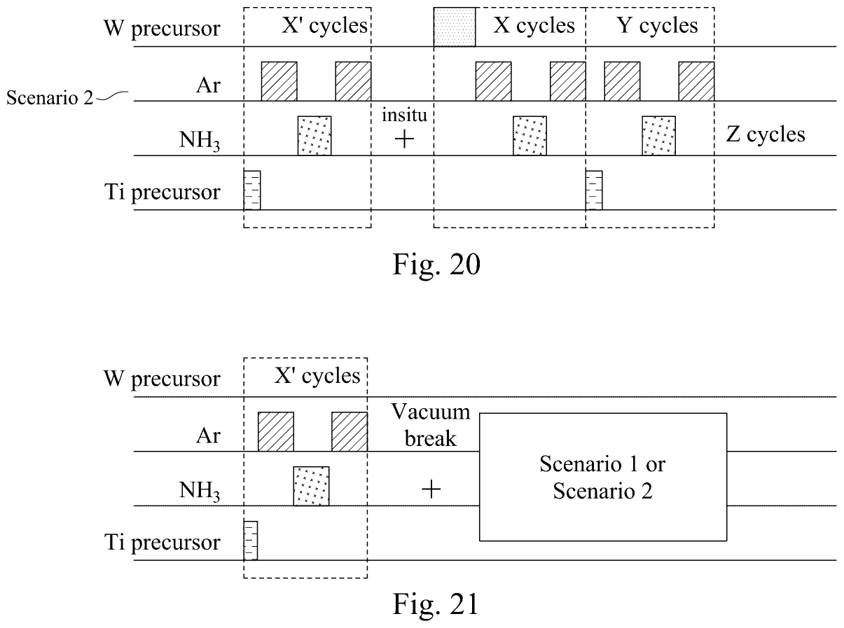

In accordance with some embodiments, the deposition of the p-type work-function layer 64P starts from the deposition of WCN, as shown in FIG. 19. In accordance with alternative embodiments, as shown in FIG. 20, a second scenario (scenario 2) is presented. In the second scenario, the deposition of the p-type work-function layer 64P starts from the deposition of TiN, followed by a WCN/TiN ternary cycle, which WCN/TiN ternary cycle may be the same as or different from the WCN/TiN ternary cycle illustrated in FIG. 19. The deposition of the TiN may be performed in-situ in the same vacuum environment as that the WCN/TiN ternary cycle, without vacuum break in between.

In accordance with some embodiments, the deposition of the entire p-type work-function layer 64P is performed in-situ in the same vacuum environment, without vacuum break in between. In accordance with alternative embodiments, a TiN layer may be deposited ex-situ with the deposition of WCN/TiN ternary cycle(s). For example, as shown in FIG. 21, a TiN layer is first deposited through ALD. A vacuum break is then performed, followed by the processes as shown in FIG. 19 or FIG. 20 to deposit more WCN/TiN ternary layers. The in-situ and ex-situ process as discussed above provides flexibility in manufacturing processes, and enable the use of either the same deposition tool or different types of deposition tools.

In accordance with some embodiments, the deposition of the p-type work-function layer 64P (and the corresponding ALD processes) may be performed at the temperatures in the range between about 200° C. and about 500° C. Each of the TiN layer and the WCN layer is kept thin to enable the inter-mixing and the formation of the ternary layers. A ternary layer including a TiN layer and a WCN layer cannot be too thick. Otherwise, the TiN layer and a WCN layer are not adequately mixed (inter-diffused into each other), and the resulting p-type work-function layer 64P will have higher resistivity and lower ability of reducing the diffusion of aluminum. In accordance with some embodiments, a ternary layer including a WCN layer and a TiN layer has a total thickness smaller than about 5 Å.

The above-presented processes adopt the formation of TiN and WCN as the first metal nitride layer and the second metal nitride layer, respectively. In accordance with alternative embodiments, other types of the first metal nitride material and second metal nitride material, as discussed above, may be used. The formation processes and the precursors are selected accordingly.

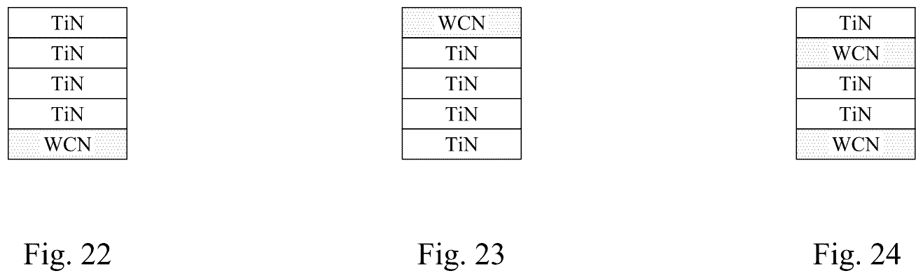

FIGS. 22 through 24 are used to explain the reason why WCN layers and TiN layers are formed as thin layers. FIG. 22 illustrates a WCN layer and a thick TiN layer over the WCN layer. FIG. 23 illustrates a thick TiN layer and a WCN layer over the thick TiN layer. These structures are viewed through transmission electron microscopy (TEM) and X-ray photoelectron spectroscopy (XPS). The resulting images revealed phase separation of the TiN layer and the WCN layer, wherein the brighter pattern of WCN and the darker pattern of TiN are observed, and are clearly separated from each other.

FIG. 24 illustrates a structure including two sub layers, each including a WCN layer sandwiched between two TiN atomic layers. The resulting TEM and XPS images revealed that the resulting structure is shown as a continuous bright pattern, with no phase separation of the WCN layers and TiN layer being observed. The TEM and XPS results of the structures in FIGS. 22 through 24 revealed that the alternatingly deposited thin WCN and TiN layers may have different crystalline structures than that of TiN and WCN layers alone, and hence may have different properties such as etching rates, resistivity, and the ability of blocking diffusion, than TiN and WCN layers alone.

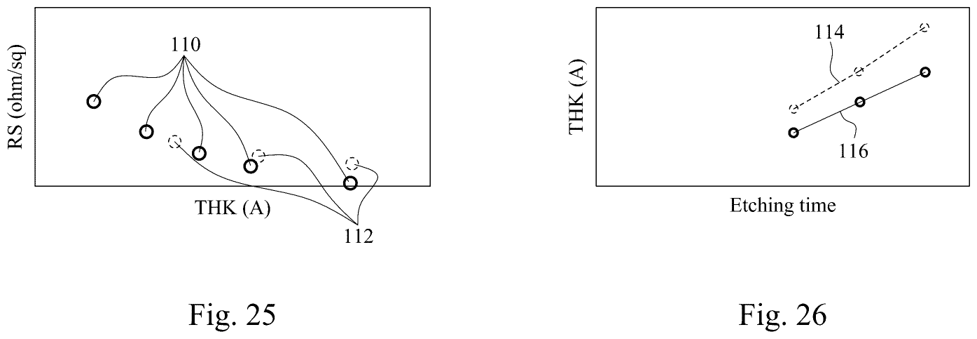

FIG. 25 illustrates the comparison of the sheet resistance values of TWN (the WCN/TiN ternary layer) and TiN, wherein the sheet resistance (Rs) values are illustrated as the function of thicknesses. Circles 110 represent the sheet resistance of TiN, and circles 112 represent the sheet resistance of TWN. FIG. 25 shows that the sheet resistance of TiN and WCN are close to each other, with TWN having slightly lower sheet resistance values than TiN.

FIG. 26 illustrates the comparison of the etching rates of TWN and TiN, wherein the etched thickness values are illustrated as the function of etching time. The sample TWN and TiN layers are formed on bare silicon substrates. Line 114 is the etching rate of TWN, and line 116 is the etching rate of TiN. FIG. 26 shows that the etching rate of TWN is higher than that of TiN, indicating that the etching of etching TWN is easy and easier than TiN. Furthermore, both of TWN and TiN have higher etching rates than WCN (not shown).

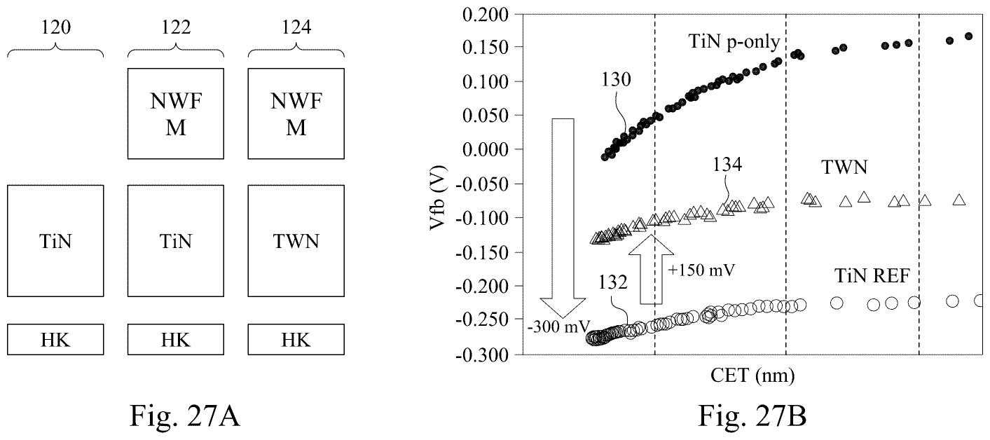

FIGS. 27A and 27B illustrate some example structures and their flat-band voltages, wherein the flat-band voltages (V_{fb}) are illustrated as the function of Capacitance Equivalent Thicknesses (CET). In FIG. 27A, three multilayer gate stacks are shown, wherein multilayer gate stack 120 has TiN (as a work-function layer) on a high-k dielectric layer, and no nWF metal is over the TiN. Multi-layer gate stack 122 has TiN as a p-type work-function layer, and further has an n-type work function (NWF) layer comprising aluminum. Layer stack 124 has TWN (WCN/TiN ternary layer, for example) and an overlying NWF layer comprising aluminum.

The flat-band voltage V_{fb} of structures 120, 122, and 124 are shown as solid circles 130, hollow circles 132, and triangles 134, respectively. It is observed that the flat-band voltages (triangles 134) of structure 124 are improved over that of the flat-band voltages (triangles 132) of structure 122 by about 150 mV, indicating that when the p-type work-function layer adopts TWN rather than TiN, the flat-band voltages may be less negative, and the threshold voltages of the transistors adopting TWN rather than TiN underlying NWF will be lower. The flat-band voltages (triangles 130) of structure 120 has the highest flat-band voltages and thus lower threshold voltages since there is no overlying aluminum existing to diffuse down and adversely affect the threshold voltages.

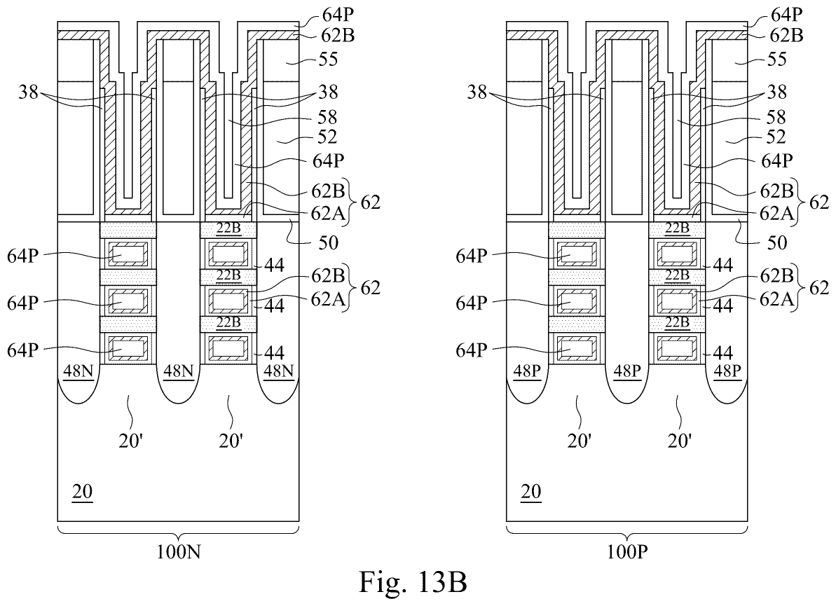

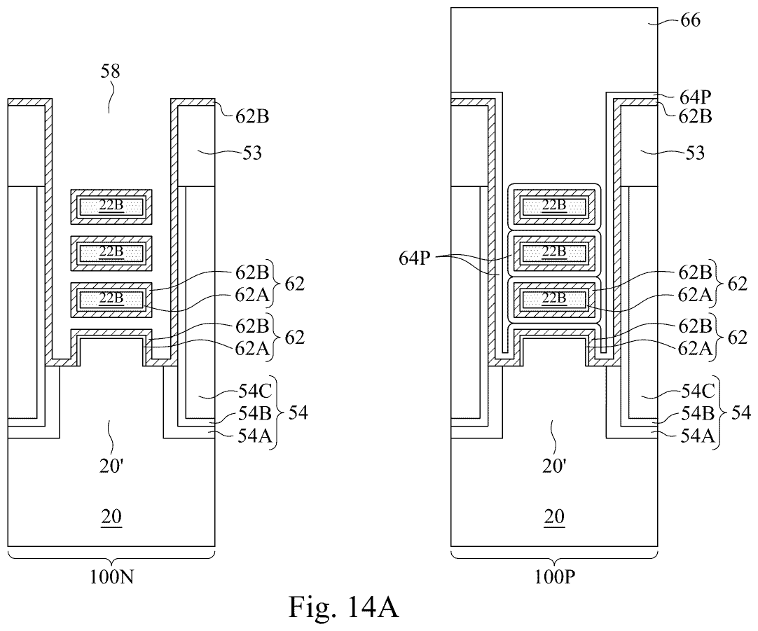

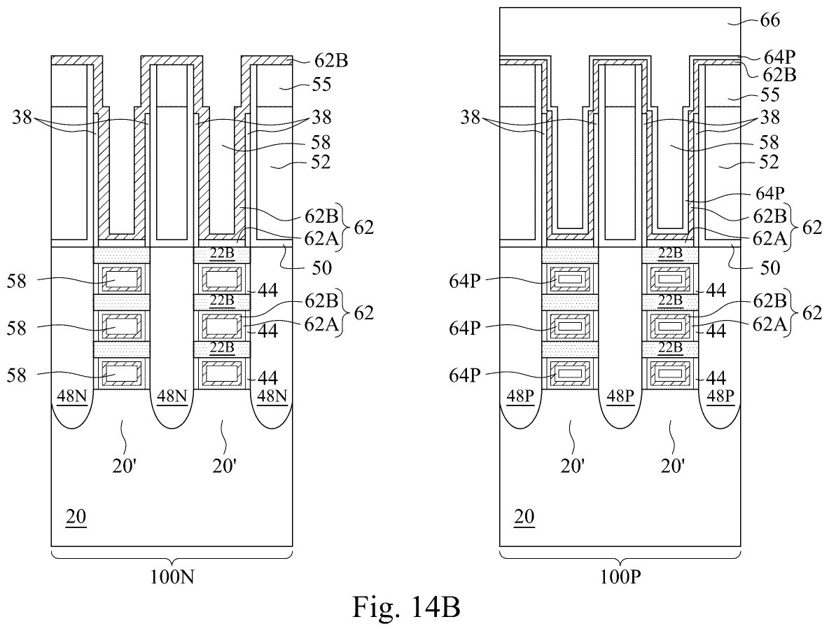

Referring to FIGS. 14A and 14B, etching mask 66 is formed to cover device region 100P. Etching mask 66 may comprise a photoresist. Next, an isotropic etching process is performed to etch and remove the portions of p-type work-function layer 64P in device region 100N, thus exposing the underlying high-k dielectric layer 62B again. The respective process is illustrated as process 230 in the process flow 200 shown in FIG. 30. The etching mask 66 is then removed.

FIGS. 15A and 15B illustrate the deposition of an n-type work-function layer 64N, which has an n-type work function (lower than about 4.5 eV, for example). The respective process is illustrated as process 232 in the process flow 200 shown in FIG. 30. In accordance with some embodiments, n-type work-function layer 64N is an aluminum-containing layer comprising TiAl, TiAlC, TiAlN, TaAlN, or the like, or combinations thereof. The deposition may be performed through ALD, CVD, or the like.

In device region 100N, the n-type work-function layer 64N is over, and may be in contact with, high-k dielectric layer 62B. In device region 100P, the n-type work-function layer 64N is over, and may be in contact with, the p-type work-function layer 64P.

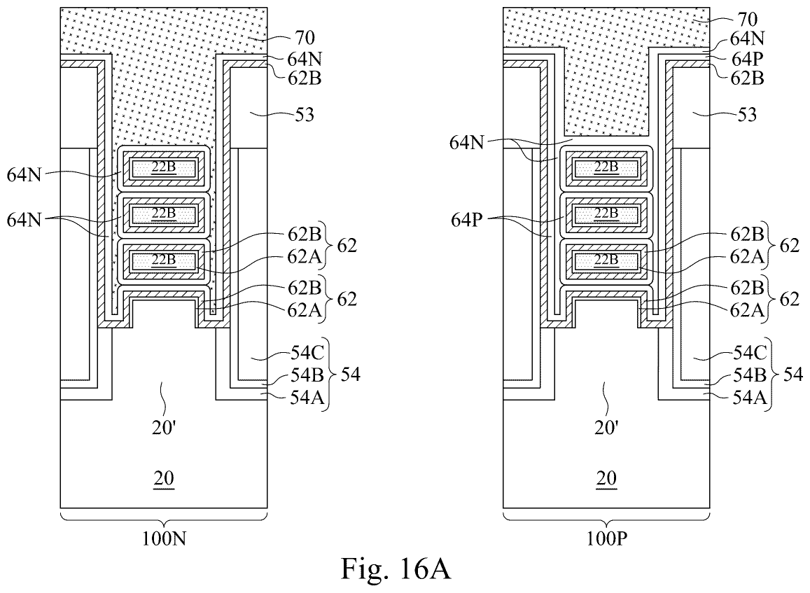

FIGS. 16A and 16B illustrate the formation of filling regions 70. The respective process is illustrated as process 234 in the process flow 200 shown in FIG. 30. Filling regions 70 may include a capping layer such as a TiN layer, and may also include a metal-containing material such as cobalt, ruthenium, aluminum, tungsten, combinations thereof, and/or multilayers thereof.

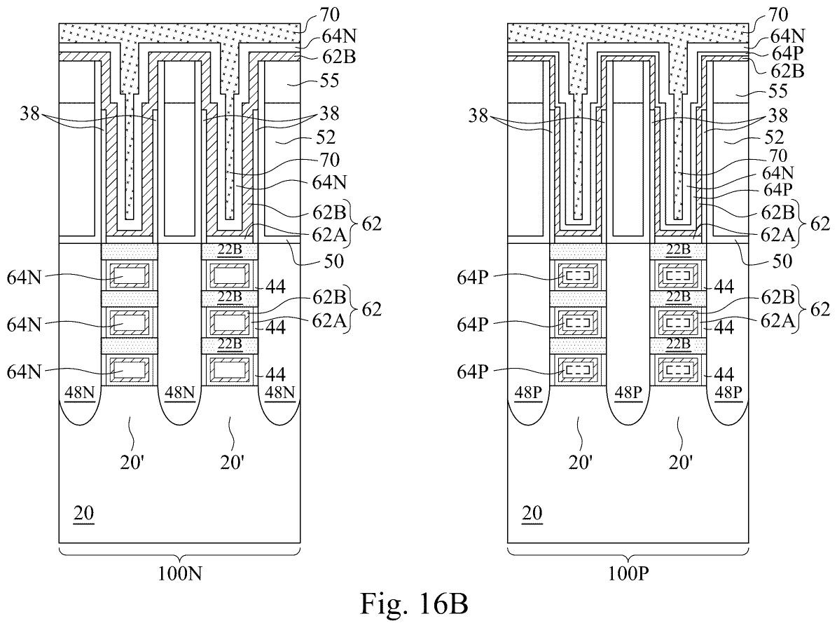

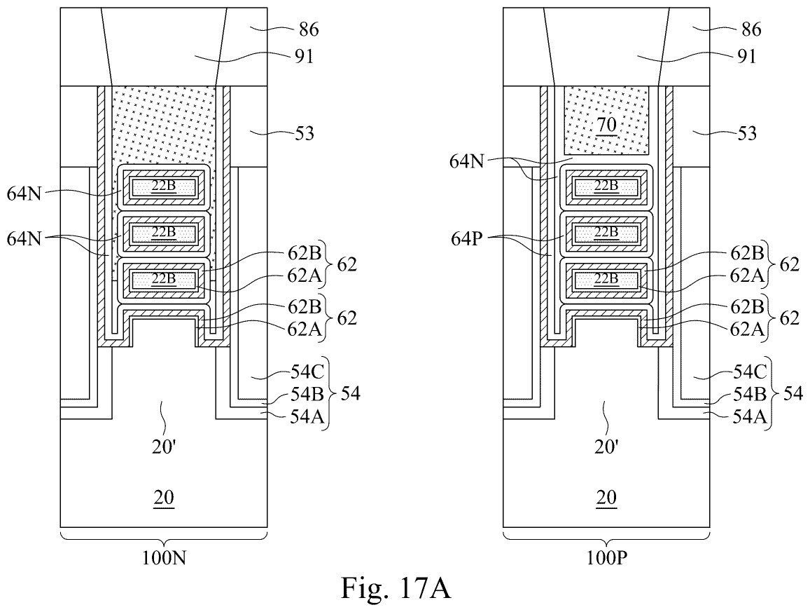

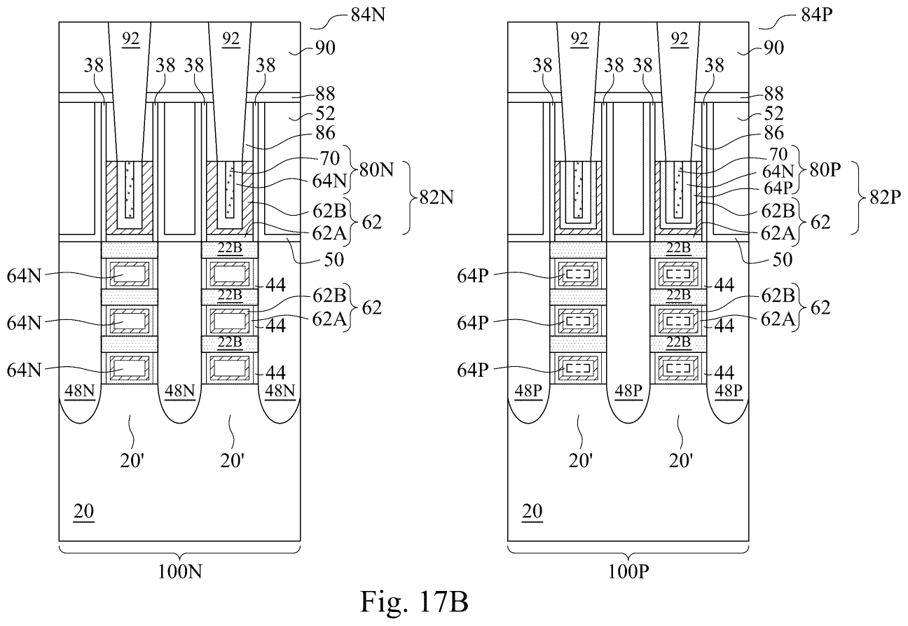

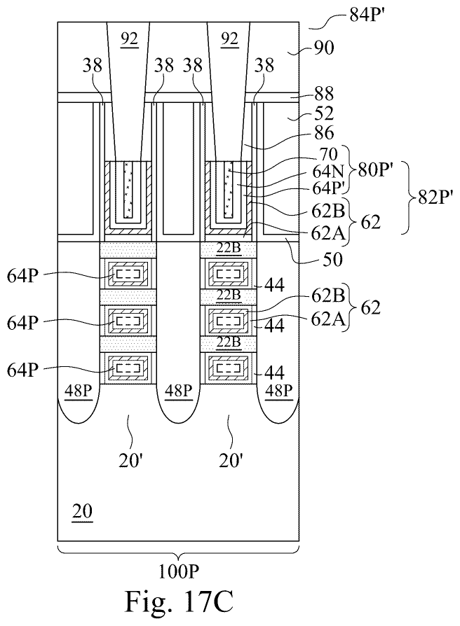

Referring to FIGS. 17A and 17B, a planarization process is performed to level and remove the excess materials in FIGS. 16A and 16B. Gate electrodes 80N and 80P and the corresponding gate stacks 82N and 82P are thus formed in device regions 100N and 100P, respectively, and n-type transistor 84N and p-type transistor 84P are formed. As shown in FIG. 17B, gate stacks 82N and 82P are recessed, and dielectric hard masks 86 are formed in the recesses. Etch stop layer 88 and ILD 90 are then formed. Gate contact plugs 92 are formed to connect to gate electrodes 80N and 80P.

In n-type transistor 100N, the n-type work-function layer 64N acts as the work-function layer of the n-type transistor 84N. In device region 100P, the p-type work-function layer 64P acts as the work-function layer of p-type transistor 84P. The n-type work-function layer 64N also has a portion overlapping the p-type work-function layer 64P in device region 100P. Since the n-type work-function layer 64N in the p-type device region 100P is farther away from the corresponding channel than the distance for it to function as an effective work-function layer, the n-type work-function layer 64N that overlaps the p-type work-function layer 64P does not act as the work-function layer of the p-type transistor 84P.

In device region 100P, the aluminum in the n-type work-function layer 64N, however, is prone to the diffusion to the underlying p-type work-function layer 64P and the underlying layers such as high-k dielectric layer 62B. This results in the reduction of the effective work function of the p-type work-function layer 64P, and results in the adverse increase in the threshold voltage of the p-type transistor 84P.

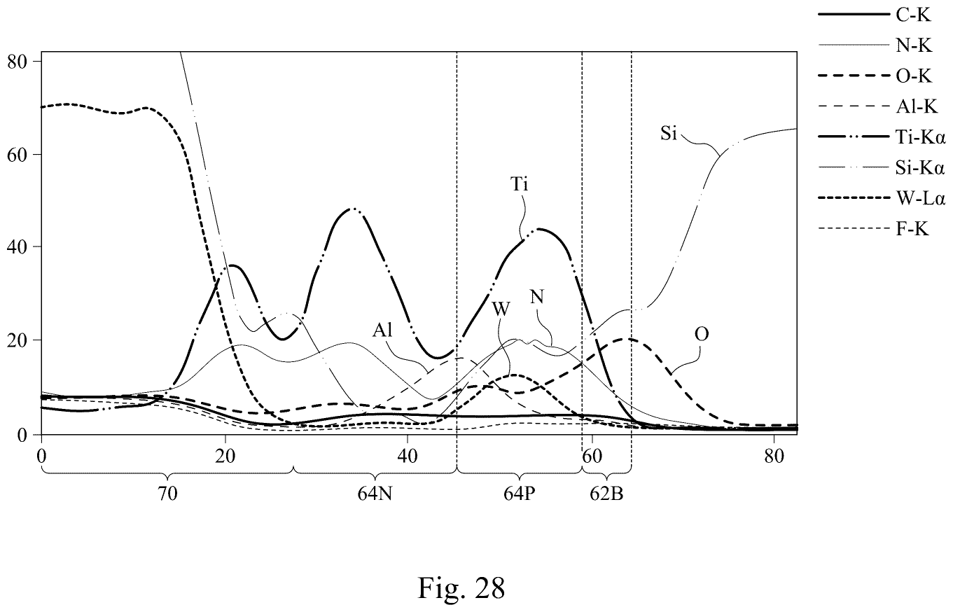

FIG. 28 illustrates an example element distribution profile of some elements including W, Ti, N, Si, O, and Al, in gate stack 82P in accordance with some embodiments. The distribution profile is obtained through Energy Dispersive X-ray Spectrometry (EDS). The high-k dielectric layer 62B, p-type work-function layer 64P, n-type work-function layer 64N, and filling region 70 are also marked. It is observed that W, Ti, and N have high concentration in the p-type work-function layer 64P due to the WCN/TiN ternary layer. The aluminum in the n-type work-function layer 64N, on the other hand, is diffused downwardly. WCN acts as an effective blocker for aluminum to diffuse into. Accordingly, aluminum is blocked at the interface between the p-type work-function layer 64P and the n-type work-function layer 64N. This results in an Al peak concentration to be generated at the interface between the p-type work-function layer 64P and the n-type work-function layer 64N, with the Al concentration gradually reduced when going into the p-type work-function layer 64P and the n-type work-function layer 64N.

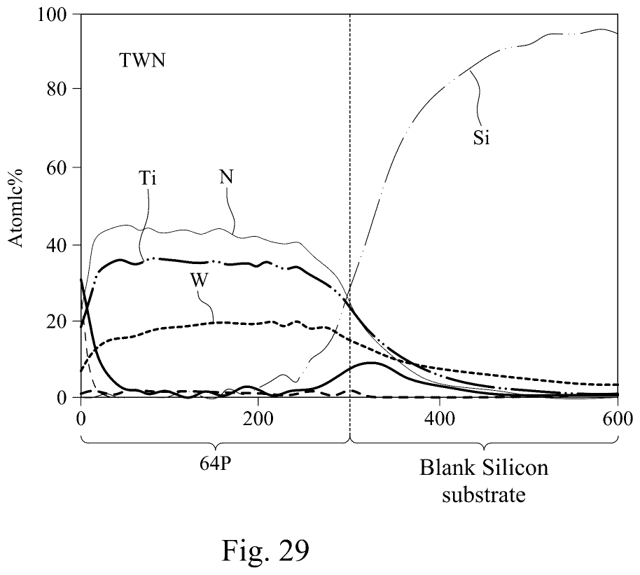

FIG. 29 illustrates an example TWN ternary layer 64P that is deposited on a blank silicon substrate sample in accordance with some embodiments. The atomic percentages of Al, W, and N are obtained through XPS. It is shown that the tungsten atomic percentage is nearly uniform throughout the TWN layer.

As addressed above, the TiN/WCN ternary layer may be deposited with the WCN ALD cycle count being equal to X (refer to FIGS. 19-21) and the TiN ALD cycle count being equal to Y in each WCN/TiN ternary cycle. This provides a tuning knob for adjusting the threshold voltage of the resulting transistors. Referring to symbols 132 and 134 in FIG. 27, it is realized that when the ratio X/Y reduces, the threshold voltage of the resulting p-type transistor may reduce. When the ratio X/Y increases, the threshold voltage of the resulting p-type transistor increases. Accordingly, by adjusting the X/Y ratio, different p-type transistors having different threshold voltages may be formed in the same device die and on the same semiconductor substrate 20. For example, FIG. 17C illustrates transistor 84P′ formed in the same device die as transistors 84N and 84P (FIGS. 17A and 17B). The transistor 84P has the ratio X/Y, and the transistor 84P′ has the ratio X′/Y′ different from ratio X/Y. Ratio X′/Y′ may be greater or smaller than ratio X/Y, resulting in the threshold voltage Vtp of transistor 84P to be different from the threshold voltage Vtp′ of transistor 84P′. Transistors 84P and 84P′ may share all above-discussed processes except the deposition of p-type work-function layer 64P and 64P′.

The embodiments of the present disclosure have some advantageous features. By adopting ternary p-type work-function layers, which may be formed by co-depositing two metal nitrides, the downward diffusion of the aluminum in the overlying n-type work-function layer is reduced. The adverse increase of the threshold voltage of the p-type transistors is reduced. On the other hand, the WCN and the WCN/TiN layers have high etching rates and low resistivity, and does not adversely affect the performance of the resulting transistors and the manufacturing process.

In accordance with some embodiments of the present disclosure, a method comprises forming a p-type transistor comprising forming a first gate dielectric on a first semiconductor region; depositing a p-type work-function layer on the first gate dielectric, wherein the p-type work-function layer comprises a metal nitride, and wherein the metal nitride comprises a first metal and a second metal; depositing a first n-type work-function layer over the p-type work-function layer; and forming a p-type source/drain region aside of the first semiconductor region. In an embodiment, the first metal comprises titanium, and the second metal is selected from tungsten (W), molybdenum (Mo), tantalum (Ta), and vanadium (V).

In an embodiment, the p-type work-function layer comprises a first metal nitride of the first metal, and a second metal nitride of the second metal. In an embodiment, the depositing the p-type work-function layer comprises depositing a first layer comprising the first metal nitride through atomic layer deposition; and depositing a second layer comprising the second metal nitride through atomic layer deposition, wherein the second metal nitride is in contact with the first metal nitride. In an embodiment, a total thickness of the first layer and the second layer is smaller than about 5 Å.

In an embodiment, the depositing the p-type work-function layer further comprises depositing a third layer comprising the first metal nitride over the second layer; and depositing a fourth layer comprising the second metal nitride over and contacting the third layer. In an embodiment, the p-type work-function layer is deposited to be in contact with the first gate dielectric. In an embodiment, the first semiconductor region comprises a plurality of semiconductor nanostructures, wherein the p-type work-function layer encircles the plurality of semiconductor nanostructures, and comprises portions between neighboring ones of the plurality of semiconductor nanostructures.

In an embodiment, the method further comprises forming an n-type transistor comprising forming a second gate dielectric on a second semiconductor region; depositing a second n-type work-function layer over the second gate dielectric; and forming an n-type source/drain region aside of the second semiconductor region. In an embodiment, the method further comprises depositing an additional p-type work-function layer on the first gate dielectric, wherein the p-type work-function layer and the additional p-type work-function layer are deposited in a same deposition process; and before the second n-type work-function layer is deposited, removing the additional p-type work-function layer from the second gate dielectric.

In accordance with some embodiments of the present disclosure, a structure comprises a plurality of semiconductor nanostructures, wherein upper ones of the plurality of semiconductor nanostructures overlap lower ones of the plurality of semiconductor nanostructures; and a gate stack comprising parts between the plurality of semiconductor nanostructures, wherein the gate stack comprises a gate dielectric on the plurality of semiconductor nanostructures; a p-type work-function layer on the gate dielectric, wherein the p-type work-function layer comprises a first metal nitride and a second metal nitride; an n-type work-function layer over the p-type work-function layer; and a metal filling region over the n-type work-function layer.

In an embodiment, the first metal nitride comprises titanium nitride. In an embodiment, the second metal nitride is selected from the group consisting of WCN, MoN, TaN, and VN. In an embodiment, the second metal nitride comprises WCN. In an embodiment, the p-type work-function layer comprises a first ternary layer, wherein the first ternary layer comprises a first metal nitride layer that comprises the first metal nitride and a second metal nitride layer that comprises the second metal nitride. In an embodiment, the p-type work-function layer further comprises a second ternary layer over the first ternary layer, wherein the second ternary layer further comprises the first metal nitride and the second metal nitride. In an embodiment, the first ternary layer has a thickness smaller than about 5 Å.

In accordance with some embodiments of the present disclosure, a structure comprises a semiconductor nanosheet; a gate stack encircling the semiconductor nanosheet, wherein the gate stack comprises a gate dielectric on the semiconductor nanosheet; a p-type work-function layer on the gate dielectric, wherein the p-type work-function layer comprises titanium nitride and tungsten carbonate nitride; an aluminum-containing layer over the p-type work-function layer; and a metal filling region over the aluminum-containing layer; and a source/drain region aside of the gate stack. In an embodiment, the source/drain region is a p-type source/drain region. In an embodiment, the gate dielectric comprises a high-k gate dielectric layer, and the p-type work-function layer physically contacts the p-type work-function layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a p-type transistor comprising:
forming a first gate dielectric on a first semiconductor region;
depositing a p-type work-function layer on the first gate dielectric, wherein the p-type work-function layer comprises a metal nitride, and wherein the metal nitride comprises a first metal and a second metal;
depositing a first n-type work-function layer over the p-type work-function layer; and
forming a p-type source/drain region aside of the first semiconductor region, wherein the first metal comprises titanium, and the second metal is selected from tungsten (W), molybdenum (Mo), tantalum (Ta), and vanadium (V), and wherein the p-type work-function layer comprises a first metal nitride of the first metal, and a second metal nitride of the second metal.
